(19) United States
(12) Patent Application Publication
(10) Pub. No.: US 2025/0338734 A1
(43) Pub. Date: Oct. 30, 2025

(54) DISPLAY DEVICE AND ELECTRONIC DEVICE INCLUDING THE SAME

(71) Applicant: Samsung Display Co., LTD., Yongin-si (KR)

(72) Inventors: DASOL JEONG, Yongin-si (KR); SEUNG-HWAN CHO, Yongin-si (KR)

(73) Assignee: Samsung Display Co., LTD., Yongin-si (KR)

(21) Appl. No.: 19/082,489

(22) Filed: Mar. 18, 2025

(30) Foreign Application Priority Data
Apr. 29, 2024 (KR) 10-2024-0056650

(51) Int. Cl. H10K 59/131; H10K 59/80

(52) U.S. Cl. CPC H10K 59/131; H10K 59/80518

(57) ABSTRACT

A display device includes: a first reflective electrode including a conductive material, an insulating layer partially covering the first reflective electrode, a first connection pattern disposed in a first contact hole of the insulating layer exposing at least a portion of the first reflective electrode and electrically connected to the first reflective electrode, a first connection electrode disposed on the insulating layer, electrically connected to the first connection pattern, and having a first electrical resistance, and a light emitting element including an electrode disposed on the insulating layer and the first connection electrode, electrically connected to the first connection electrode, and having a second electrical resistance greater than the first electrical resistance.

### CROSS-REFERENCE TO RELATED APPLICATION(S)

This application claims priority to and benefits of Korean Patent Application No. 10-2024-0056650 under 35 U.S.C. § 119, filed on Apr. 29, 2024 in the Korean Intellectual Property Office (KIPO), the entire contents of which are incorporated herein by reference.

### BACKGROUND

### 1. Technical Field

Embodiments provide generally to a display device. More particularly, embodiments relate to a flat display device.

### 2. Description of the Related Art

As information technology develops, the importance of a display device, which is a connecting medium between users and information, is emerging. Recently, a head mounted display (HMD) including such a display device has been developed. A head-mounted display is a glasses-type monitor device of virtual reality (VR) or augmented reality (AR) that is worn in the form of glasses, a helmet, or the like and focuses on a distance near the user's eyes.

### SUMMARY

Embodiments provide a display device capable of improving electrical characteristics.

However, embodiments are not limited to those set forth herein. The above and other embodiments will become more apparent to one of ordinary skill in the art to which the disclosure pertains by referencing the detailed description of the disclosure given below.

A display device according to embodiments includes a first reflective electrode including a conductive material, an insulating layer partially covering the first reflective electrode, a first connection pattern disposed in a first contact hole of the insulating layer exposing at least a portion of the first reflective electrode and electrically connected to the first reflective electrode, a first connection electrode disposed on the insulating layer, electrically connected to the first connection pattern, and having a first electrical resistance, and a light emitting element including a first electrode disposed on the insulating layer and the first connection electrode, electrically connected to the first connection electrode, and having a second electrical resistance greater than the first electrical resistance.

In an embodiment, the first connection electrode may overlap the first contact hole in a plan view and cover the first connection pattern.

In an embodiment, the first electrode may be electrically connected to the first reflective electrode through the first connection electrode and the first connection pattern.

In an embodiment, the first connection electrode may contact the first electrode and the first connection pattern between the first electrode and the first connection pattern.

In an embodiment, the first electrode may not contact the first connection pattern.

In an embodiment, the display device may further include a pixel defining layer disposed on the insulating layer, partially covering the first electrode, and defining a pixel opening exposing a portion of the first electrode. The first connection electrode may overlap the pixel defining layer in a plan view.

In an embodiment, the first connection electrode may be spaced apart from the pixel opening in a plan view.

In an embodiment, the first electrode may have a step section defined along a sidewall of the first connection electrode, and the pixel defining layer may cover the step section of the first electrode.

In an embodiment, the first connection electrode and the first electrode may include different materials.

In an embodiment, the first electrode may include a transparent conductive oxide.

In an embodiment, the first connection electrode may include at least one of metal, alloy, and conductive metal nitride.

In an embodiment, the display device may further include a transistor electrically connected to the first reflective electrode and that drives the light emitting element.

In an embodiment, the first electrode may be electrically connected to the transistor through the first connection electrode, the first connection pattern, and the first reflective electrode.

In an embodiment, the insulating layer may include an inorganic material and has light transparency.

In an embodiment, the light emitting element may include an intermediate layer disposed on the first electrode and including a light emitting material and a second electrode disposed on the intermediate layer.

In an embodiment, the display device may further include an auxiliary electrode disposed on the insulating layer. The auxiliary electrode and the first electrode may include a same material. The second electrode may contact the auxiliary electrode in an area.

In an embodiment, the display device may further include a second reflective electrode disposed under the auxiliary electrode in the area and partially covered by the insulating layer, the second reflective electrode and the first reflective electrode including a same material, a second connection pattern disposed in a second contact hole of the insulating layer exposing at least portion of the second reflective electrode and electrically connected to the second reflective electrode, and a second connection electrode disposed on the insulating layer and electrically connected to the second connection pattern The second connection electrode and the first connection electrode may include a same material. The second connection electrode may have the first electrical resistance and the auxiliary electrode may have the second electrical resistance.

In an embodiment, the second connection electrode may overlap the second contact hole in a plan view and cover the second connection pattern.

In an embodiment, the auxiliary electrode may be electrically connected to the second reflective electrode through the second connection electrode and the second connection pattern.

In an embodiment, the second connection electrode may contact the auxiliary electrode and the second connection pattern between the auxiliary electrode and the second connection pattern, and the auxiliary electrode may not contact the second connection pattern.

An electronic device according to embodiments includes a display device and a processor which controls the display device, the display device includes: a first reflective electrode including a conductive material, an insulating layer partially covering the first reflective electrode, a first connection pattern disposed in a first contact hole of the insulating layer exposing at least a portion of the first reflective electrode and electrically connected to the first reflective electrode, a first connection electrode disposed on the insulating layer, electrically connected to the first connection pattern, and having a first electrical resistance, and a light emitting element including a first electrode disposed on the insulating layer and the first connection electrode, electrically connected to the first connection electrode, and having a second electrical resistance greater than the first electrical resistance.

In a display device according to embodiments, a first electrode (e.g., anode electrode) of a light emitting element may be electrically connected to a transistor through a connection electrode, a connection pattern, and a reflective electrode. For example, the electrical resistance of the connection electrode may be smaller than the electrical resistance of the first electrode, and the connection electrode may cover the connection pattern between the first electrode and the connection pattern.

Accordingly, the first electrode may be electrically connected to the connection pattern through the connection electrode while not contacting the connection pattern. Accordingly, deterioration of the electrical characteristics of the display device due to contact between the connection pattern and the first electrode, which has a relatively high electrical resistance, may be prevented. For example, since the connection electrode has a relatively small electrical resistance, although the connection electrode contacts the connection pattern, the contact resistance between the connection electrode and the connection pattern may be formed to be relatively small. Therefore, the electrical characteristics of the display device may not be affected. Accordingly, the electrical characteristics of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic plan view showing a display device according to an embodiment.

FIG. 2 is a schematic cross-sectional view showing an example taken along line I-I′ of FIG. 1.

FIGS. 3, 4, 5, 6, 7, 8, 9, 10, and 11 are schematic cross-sectional views showing a method of manufacturing the display device of FIG. 2.

FIG. 12 is a schematic cross-sectional view showing another example taken along line I-I′ of FIG. 1.

FIG. 13 is a schematic block diagram illustrating an electronic device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

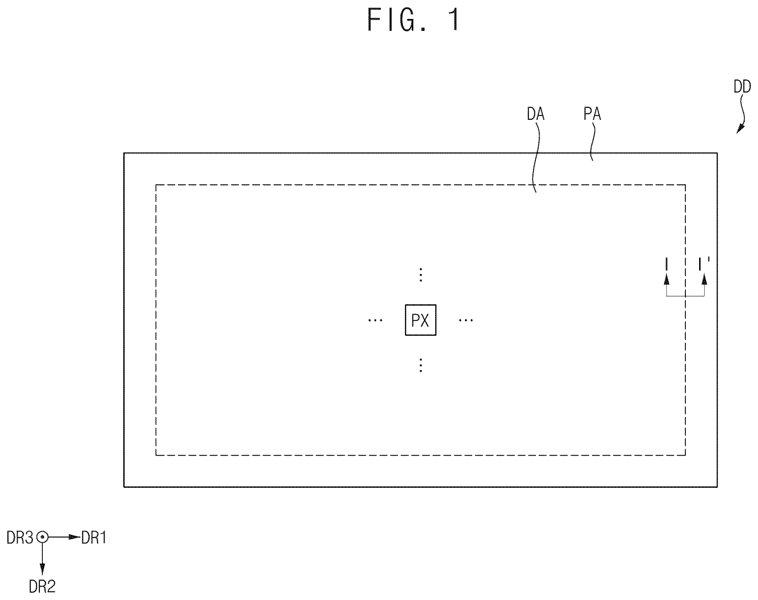

FIG. 1 is a schematic plan view showing a display device according to an embodiment.

Referring to FIG. 1, a display device DD according to an embodiment may include a display area DA and a peripheral area PA.

The display area DA may be an area that displays an image. In the display area DA, pixels PX may be repeatedly arranged along a first direction DR1 and a second direction DR2 intersecting the first direction DR1 in a plan view. For example, the second direction DR2 may be perpendicular to the first direction DR1. Each of pixels PX may be defined as the minimum light emitting unit capable of displaying light.

Signal lines such as a gate line and a data line may be disposed in the display area DA. The signal lines may be connected to each of the pixels PX. Each of the pixels PX may receive a gate signal, data signal, and the like from the signal lines. Accordingly, in the display area DA, an image may be displayed in the third direction DR3 intersecting each of the first direction DR1 and the second direction DR2. For example, the third direction DR3 may be perpendicular to the first direction DR1 and the second direction DR2, respectively.

The peripheral area PA may be an area positioned around the display area DA. For example, the peripheral area PA may surround (e.g., entirely surround) the display area DA. Drivers for displaying images in the display area DA may be disposed in the peripheral area PA. In an embodiment, the peripheral area PA may be an area that does not display an image. However, embodiments are not limited thereto, and the image may be displayed in some areas of the peripheral area PA.

In an embodiment, the display device DD may be a micro light emitting diode display device including a micro light emitting diode as a light emitting element. However, embodiments are not limited thereto.

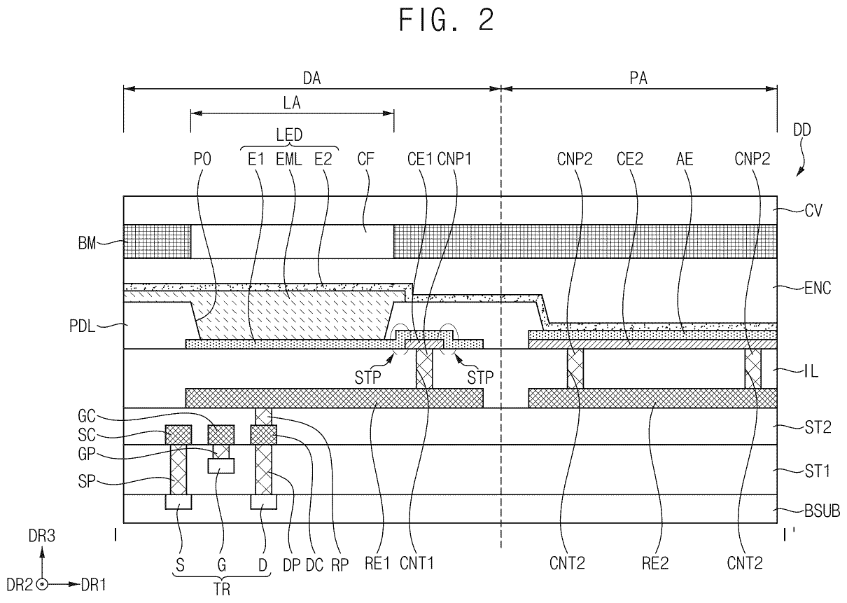

FIG. 2 is a schematic cross-sectional view showing an example taken along line I-I′ of FIG. 1.

Referring to FIGS. 1 and 2, the display device DD may include a base substrate BSUB, a first structure ST1, a second structure ST2, a transistor TR, first, second, and third terminal connection part SP, DP, and GP, first, second, and third terminal electrodes SC, DC, and GC, an electrode connection part RP, a first reflective electrode RE1, a first connection pattern CNP1, a first connection electrode CE1, a pixel defining layer PDL, a light emitting element LED, an encapsulation layer ENC, a light blocking member BM, a color filter CF, and a cover member CV.

In an embodiment, the transistor TR may be disposed in the display area DA. The transistor TR may include a first terminal S, a second terminal D, a semiconductor layer (e.g., a portion between the first terminal S and the second terminal D), and a third terminal G. For example, the first terminal S may be a source terminal, and the second terminal D may be a drain terminal. However, embodiments are not limited thereto, and the first terminal S may be a drain terminal, and the second terminal D may be a source terminal. The third terminal G may be a gate terminal.

The light emitting element LED may be disposed in the display area DA. The light emitting element LED may include a first electrode E1, an intermediate layer ML, and a second electrode E2. For example, the first electrode E1 may function as an anode, and the second electrode E2 may function as a cathode. However, embodiments are not limited thereto.

In an embodiment, the base substrate BSUB may be a semiconductor circuit board. For example, the base substrate BSUB may be a silicon wafer. However, embodiments are not limited thereto. In an embodiment, a groove may be defined in the base substrate BSUB, and the first terminal S and the second terminal D of the transistor TR may be disposed in the groove. However, embodiments are not limited thereto.

In an embodiment, the third terminal G of the transistor TR and the first structure ST1 may be disposed on the base substrate BSUB. For example, the third terminal G of the transistor TR may be insulated from the base substrate BSUB by the first structure ST1.

The first structure ST1 may be disposed in the display area DA and the peripheral area PA. The first structure ST1 may define contact holes that respectively expose the first terminal S, the second terminal D, and the third terminal G of the transistor TR. In an embodiment, the first structure ST1 may include an organic insulating layer and/or an inorganic insulating layer. The first structure ST1 may have a single-layer structure or a multi-layer structure in which insulating layers are stacked.

The first, second, and third terminal connection part SP, DP, and GP may be disposed on the base substrate BSUB. For example, the first, second, and third terminal connection parts SP, DP, and GP may be respectively disposed in the contact holes of the first structure ST1.

For example, the first terminal connection part SP may be disposed in a contact hole of the first structure ST1 exposing the first terminal S, the second terminal connection part DP may be disposed in a contact hole of the first structure ST1 exposing the second terminal D, and the third terminal connection part GP may be disposed in a contact hole of the first structure ST1 exposing the third terminal G.

For example, the first terminal connection part SP may fill the contact hole of the first structure ST1 exposing the first terminal S, the second terminal connection part DP may fill the contact hole of the first structure ST1 exposing the second terminal D, and the third terminal connection part GP may fill the contact hole of the first structure ST1 exposing the third terminal G.

Each of the first, second, and third terminal connection parts SP, DP, and GP may include a conductive material. Examples of the conductive material, which is used as the first, second, and third terminal connection parts SP, DP, and GP, may include metal, alloy, conductive metal oxide, conductive metal nitride, and the like. These can be used alone or in combination with each other. For example, each of the first, second, and third terminal connectors SP, DP, and GP may include tungsten (W).

The first, second, and third terminal electrodes SC, DC, and GC may be disposed on the first structure ST1. Each of the first, second, and third terminal electrodes SC, DC, and GC may include a conductive material. Examples of the conductive materials, which are used as the first, second, and third terminal electrodes SC, DC, and GC, may include metals, alloys, conductive metal oxides, conductive metal nitrides, and the like. These may be used alone or in combination with each other. Each of the first, second, and third terminal electrodes SC, DC, and GC may have a single-layer structure or a multi-layer structure in which conductive layers are stacked.

The first terminal electrode SC may be disposed on the first terminal connection part SP. The first terminal electrode SC may be electrically connected to the first terminal S through the first terminal connection part SP. For example, the first terminal connection part SP may contact the first terminal electrode SC and the first terminal S.

The second terminal electrode DC may be disposed on the second terminal connection part DP. The second terminal electrode DC may be electrically connected to the second terminal D through the second terminal connection part DP. For example, the second terminal connection part DP may contact the second terminal electrode DC and the second terminal D.

The third terminal electrode GC may be disposed on the third terminal connection part GP. The third terminal electrode GC may be connected to the third terminal G through the third terminal connection part GP. For example, the third terminal connection part GP may contact the third terminal electrode GC and the third terminal G.

In an embodiment, the second structure ST2 may be disposed on the first structure ST1. The second structure ST2 may be disposed in the display area DA and the peripheral area PA. The second structure ST2 may cover the first to third terminal electrodes SC, DC, and GC. In an embodiment, the second structure ST2 may include an organic insulating layer and/or an inorganic insulating layer. The second structure ST2 may have a single-layer structure or a multi-layer structure in which insulating layers are stacked. The second structure ST2 may define a contact hole exposing the second terminal electrode DC.

The electrode connection part RP may be disposed on the first structure ST1. For example, the electrode connection part RP may be disposed in the contact hole of the second structure ST2 exposing the second terminal electrode DC. For example, the electrode connection part RP may fill the contact hole of the second structure ST2 exposing the second terminal electrode DC.

The electrode connection part RP may include a conductive material. Examples of the conductive material, which are used as the electrode connection part RP, may include metal, alloy, conductive metal oxide, conductive metal nitride, and the like. These may be used alone or in combination with each other. For example, the electrode connection part RP may include tungsten (W).

The first reflective electrode RE1 may be disposed in the display area DA on the second structure ST2. The first reflective electrode RE1 may have reflectivity to reflect incident light.

The first reflective electrode RE1 may include a conductive material. Examples of the conductive material, which are used as the first reflective electrode RE1, may include metal, alloy, conductive metal oxide, conductive metal nitride, and the like. These may be used alone or in combination with each other. The first reflective electrode RE1 may have a single-layer structure or a multi-layer structure in which conductive layers are stacked.

The first reflective electrode RE1 may be disposed on the electrode connection part RP. The first reflective electrode RE1 may be electrically connected to the second terminal electrode DC through the electrode connection part RP. For example, the electrode connection part RP may contact the first reflective electrode RE1 and the second terminal electrode DC. As a result, the first reflective electrode RE1 may be electrically connected to the transistor TR.

The insulating layer IL may be disposed on the second structure ST2 and the first reflective electrode RE1. The insulating layer IL may be disposed in the display area DA and the peripheral area PA. The insulating layer IL may partially cover the first reflective electrode RE1. The insulating layer IL may define a first contact hole CNT1 exposing a portion of the first reflective electrode RE1.

In an embodiment, the insulating layer IL may include an inorganic material. Examples of the inorganic materials, which are used as the insulating layer IL, may include silicon oxide, silicon nitride, silicon oxynitride, and the like. These may be used alone or in combination with each other. The insulating layer IL may have a single-layer structure or a multi-layer structure in which insulating layers are stacked.

The insulating layer IL may have light transparency. For example, the insulating layer IL may transmit light emitted from the light emitting element LED and light reflected from the first reflective electrode RE1. For example, since the insulating layer IL has light transparency, light emitted from the light emitting element LED may pass through the insulating layer IL and reach the first reflective electrode RE1. For example, since the first reflective electrode RE1 has reflectivity and the insulating layer IL has light transparency, the light that reaches the first reflective electrode RE1 may be reflected by the first reflective electrode RE1 and then be emitted toward the outside of the display device DD through the light emitting element LED. Accordingly, the loss of light emitted from the light emitting element LED may be reduced, and the luminous efficiency of the display element LED may be improved or enhanced.

The first connection pattern CNP1 may be disposed on the first reflective electrode RE1. For example, the first connection pattern CNP1 may be disposed in the first contact hole CNT1 of the insulating layer IL exposing the first reflective electrode RE1. For example, the first connection pattern CNP1 may fill the first contact hole CNT1 of the insulating layer IL exposing the first reflective electrode RE1.

The first connection pattern CNP1 may include a conductive material. Examples of the conductive material, which are used as the first connection pattern CNP1, may include metal, alloy, conductive metal oxide, conductive metal nitride, and the like. These may be used alone or in combination with each other. For example, the first connection pattern CNP1 may include tungsten (W).

The first connection electrode CE1 may be disposed in the display area DA on the insulating layer IL. The first connection electrode CE1 may be disposed on the first connection pattern CNP1. For example, the first connection electrode CE1 may overlap the first connection pattern CNP1 in a plan view and cover the first connection pattern CNP1. For example, the first connection electrode CE1 may cover the first connection pattern CNP1 exposed from the insulating layer IL.

The first connection electrode CE1 may include a conductive material. Examples of the conductive material, which are used as the first connection electrode CE1, may include metal, alloy, conductive metal oxide, conductive metal nitride, and the like. These may be used alone or in combination with each other. The first connection electrode CE1 may have a single-layer structure or a multi-layer structure in which conductive layers are stacked.

For example, the first connection electrode CE1 may include titanium (Ti) and/or titanium nitride (TiN). In case that the first connection electrode CE1 includes titanium (Ti) and/or titanium nitride (TiN), durability of the first connection electrode CE1 may be further improved or enhanced.

The first connection electrode CE1 may be electrically connected to the first connection pattern CNP1. For example, the first connection electrode CE1 may contact the first connection pattern CNP1. For example, the first connection electrode CE1 may contact the first connection pattern CNP1 exposed from the insulating layer IL. As a result, the first connection electrode CE1 may be electrically connected to the first reflective electrode RE1 through the first connection pattern CNP1. For example, the first connection electrode CE1 may be electrically connected to the transistor TR through the first connection pattern CNP1 and the first reflective electrode RE1.

For example, the first connection electrode CE1 may have a first electrical resistance. The first electrical resistance may be smaller than the electrical resistance of the first electrode E1, which will be described later. This will be described in more detail later.

The first electrode E1 may be disposed in the display area DA on the insulating layer IL. The first electrode E1 may be disposed on the first connection electrode CE1. For example, the first electrode E1 may overlap the first connection electrode CE1 in a plan view. For example, the first electrode E1 may cover the first connection electrode CE1.

The first electrode E1 may have a second electrical resistance greater than the first electrical resistance of the first connection electrode CE1. For example, the electrical resistance of the first connection electrode CE1 may be smaller than the electrical resistance of the first electrode E1. For example, the material included in the first connection electrode CE1 may be a material having a smaller electrical resistance than the material included in the first electrode E1. For example, the material included in the first electrode E1 may be different from the material included in the first connection electrode CE1.

The first electrode E1 may include a conductive material. An example of the conductive material, which is used as the first electrode E1, may be a transparent conductive oxide. For example, the first electrode E1 may include indium tin oxide (ITO), indium gallium zinc oxide (IGZO), indium tin zinc oxide (ITZO), indium zinc oxide (IZO), indium gallium oxide (IGO), zinc oxide. (ZnO), indium oxide (InO), tin oxide (SnO), gallium oxide (GaO), aluminum zinc oxide (AZO), and the like. These may be used alone or in combination with each other. The first electrode E1 may have a single-layer structure or a multi-layer structure in which conductive layers are stacked.

As the first electrode E1 includes a transparent conductive oxide, the transmittance of light reflected by the first reflective electrode RE1 and reaching the first electrode E1 may be improved or enhanced. Accordingly, the luminous efficiency of the display device DD may be improved or enhanced.

The first electrode E1 may be electrically connected to the first connection electrode CE1. For example, the first electrode E1 may contact the first connection electrode CE1. For example, the first connection electrode CE1 may contact the first electrode E1 and the first connection pattern CNP1 between the first electrode E1 and the first connection pattern CNP1. As a result, the first electrode E1 may be electrically connected to the first connection pattern CNP1 through the first connection electrode CE1.

For example, the first electrode E1 may be electrically connected to the first reflective electrode RE1 through the first connection electrode CE1 and the first connection pattern CNP1. As a result, the first electrode E1 may be electrically connected to the transistor TR through the first connection electrode CE1, the first connection pattern CNP1, and the first reflective electrode RE1. Accordingly, the first electrode E1 may receive a power supply voltage (e.g., a high-power supply voltage) from the transistor TR. Accordingly, the transistor TR may drive the light emitting element LED.

For example, the first electrode E1 may be electrically connected to the first connection pattern CNP1 by the first connection electrode CE1, the first electrode E1 may not contact the first connection pattern CNP1. For example, the first connection electrode CE1 may cover the first connection pattern CNP1 between the first electrode E1 and the first connection pattern CNP1, and accordingly, the first electrode E1 may not contact the first connection pattern CNP1. For example, the first connection pattern CNP1 may not be exposed by the first connection electrode CE1, and accordingly, the first electrode E1 may not contact the first connection pattern CNP1.

In case that the first electrode E1, which has a relatively large electrical resistance, contacts the first connection pattern CNP1, the contact resistance between the first electrode E1 and the first connection pattern CNP1 may be large. Accordingly, the electrical characteristics of the display device DD may deteriorate or degrade.

According to an embodiment, the electrical resistance of the first connection electrode CE1 may be smaller than the electrical resistance of the first electrode E1, and the first connection electrode CE1 may cover the first connection pattern CNP1 between the first electrode E1 and the first connection pattern CNP1. Accordingly, the first electrode E1 may be electrically connected to the first connection pattern CNP1 through the first connection electrode CE1 while not contacting the first connection pattern CNP1. Accordingly, deterioration of the electrical characteristics of the display device DD due to contact between the first electrode E1, which has a relatively high electrical resistance, and the first connection pattern CNP1 may be prevented. For example, since the first connection electrode CE1 has a relatively small electrical resistance, although the first connection electrode CE1 contacts the first connection pattern CNP1, the contact resistance between the first connection electrode CE1 and the first connection pattern CNP1 may be formed to be relatively small. Accordingly, the electrical characteristics of the display device DD may not be affected. Accordingly, the electrical characteristics of the display device DD may be improved or enhanced.

In an embodiment, the first electrode E1 may have a step section STP defined along a sidewall of the first connection electrode CE1. For example, a portion of the upper surface of the first electrode E1 may have a step due to the first connection electrode CE1 and may not be substantially flat.

The pixel defining layer PDL may be disposed on the insulating layer IL and the first electrode E1. The pixel defining layer PDL may include an organic insulating material and/or an inorganic insulating material.

The pixel defining layer PDL may partially cover the first electrode E1. For example, the pixel defining layer PDL may define a pixel opening PO exposing a portion of the first electrode E1. The intermediate layer ML including a light emitting material may be disposed on the first electrode E1 exposed by the pixel opening PO.

The pixel defining layer PDL may overlap the first connection electrode CE1 in a plan view. For example, the pixel defining layer PDL may overlap (e.g., entirely overlap) the first connection electrode CE1 in a plan view. Accordingly, the first connection electrode CE1 may be spaced apart from the pixel opening PO in a plan view. For example, the pixel defining layer PDL may be disposed on the first connection electrode CE1 to cover the step section STP of the first electrode E1. Accordingly, the step section STP of the first electrode E1 may not be exposed by the pixel opening PO of the pixel defining layer PDL.

In case that the intermediate layer ML is disposed on the step section STP of the first electrode E1, the thickness uniformity of the intermediate layer ML may decrease, and the light emitting characteristics of the light emitting element LED may decrease.

According to an embodiment, the pixel defining layer PDL may cover the step section STP of the first electrode E1, and the step section STP of the first electrode E1 may may not be exposed by the pixel opening PO of the pixel defining layer PDL. Accordingly, a portion of the upper surface of the first electrode E1 exposed by the pixel opening PO may be substantially flat. For example, the step section STP of the first electrode E1 may not affect the thickness uniformity of the intermediate layer ML. Accordingly, the step section STP of the first electrode E1 may not affect the light emitting characteristics of the light emitting element LED (e.g., the intermediate layer ML). For example, in case that the first electrode E1 has the step section STP due to the first connection electrode CE1, the light emitting characteristics of the light emitting element LED (e.g., the intermediate layer ML) may not deteriorate or degrade.

The intermediate layer ML may be disposed on the first electrode E1. The intermediate layer ML may be disposed on the first electrode E1 exposed by the pixel opening PO. The intermediate layer ML may include a functional layer including an organic material and a light emitting layer including a light emitting material. For example, the functional layer may include a hole injection layer, a hole transport layer, an electron transport layer, an electron injection layer, a charge generation layer, and the like.

In an embodiment, the intermediate layer ML may emit white light. For example, the intermediate layer ML may have a structure in which light emitting layers are stacked in the third direction DR3, and the intermediate layer ML may emit white light through a combination of light emitted by each of the light emitting layers. For example, the intermediate layer ML may have a tandem structure. For example, the functional layer may be disposed on and/or under each of the light emitting layers.

The second electrode E2 may be disposed on the intermediate layer ML. The second electrode E2 may include a conductive material. Examples of the conductive material, which are used as the second electrode E2, may include metal, alloy, conductive metal oxide, conductive metal nitride, transparent conductive oxide, and the like. These may be used alone or in combination with each other. In an embodiment, the second electrode E2 may have semi-transparency or transparency. For example, the second electrode E2 may extend to the peripheral area PA. This will be described in more detail later.

The encapsulation layer ENC may be disposed on the second electrode E2. The encapsulation layer ENC may protect the light emitting element LED from external foreign substances. The encapsulation layer ENC may include at least one inorganic encapsulation layer and at least one organic encapsulation layer.

The light blocking member BM and the color filter CF may be disposed on the encapsulation layer ENC.

In an embodiment, the light blocking member BM may be disposed in the display area DA and the peripheral area PA. Light incident on the light blocking member BM may be absorbed and/or blocked by the light blocking member BM and may not proceed to the outside of the display device DD. For example, the light blocking member BM may define the light emitting area LA by dividing a light emitting area LA.

In an embodiment, the light blocking member BM may include a light blocking material. For example, the light blocking member BM may include an organic material and/or an inorganic material including black pigment, black dye, and the like. However, embodiments are not limited thereto, and the light blocking member BM may have a structure in which color filters of different colors are stacked in the third direction DR3. For example, since the light blocking member BM and the color filter CF may be formed in the same process, process cost and time may be reduced.

The color filter CF may be disposed to correspond to (or to overlap) the light emitting area LA. The color filter CF may transmit light in a wavelength band of a specific color and absorb and/or block light in wavelength bands other than the specific color. Accordingly, the light emitted from the light emitting element LED may be converted (or filtered) into light in the wavelength band of the specific color through the color filter CF. Accordingly, the color of light emitted from the light emitting area LA may be determined by the color filter CF.

The cover member CV may be disposed on the light blocking member BM and the color filter CF. The cover member CV may protect components disposed under the cover member CV. For example, the cover member CV may be a window including glass. However, embodiments are not limited thereto.

In an embodiment, an optical functional layer changing the path of light may be additionally disposed on the light blocking member BM and the color filter CF. For example, the optical functional layer may include micro lenses, a polarizing layer, a phase retardation layer, and the like.

According to an embodiment, the first reflective electrode RE1 may be disposed under the first electrode E1 of the light emitting element LED, and the insulating layer IL having light transparency may be disposed between the first electrode E1 and the first reflective electrode RE1. Accordingly, the light emitted from the light emitting element LED may pass through the insulating layer IL and reach the first reflective electrode RE1, and the light that reaches the first reflective electrode RE1 may be reflected by the first reflective electrode RE1 and then be emitted toward the outside of the display device DD through the light emitting element LED. Accordingly, the loss of light emitted from the light emitting element LED may be reduced, and the luminous efficiency of the display device DD may be improved or enhanced.

For example, the first electrode E1 of the light emitting element LED may be electrically connected to the transistor TR through the first connection electrode CE1, the first connection pattern CNP1, and the first reflection electrode RE1. For example, the electrical resistance of the first connection electrode CE1 may be smaller than the electrical resistance of the first electrode E1, and the first connection electrode CE1 may cover the first connection pattern CNP1 between the first electrode E1 and the first connection pattern CNP1. Accordingly, the first electrode E1 may be electrically connected to the first connection pattern CNP1 through the first connection electrode CE1 while not contacting the first connection pattern CNP1. Accordingly, deterioration of the electrical characteristics of the display device DD due to contact between the first electrode E1, which has a relatively high electrical resistance, and the first connection pattern CNP1 may be prevented. For example, since the first connection electrode CE1 has a relatively small electrical resistance, although the first connection electrode CE1 contacts the first connection pattern CNP1, the contact resistance between the first connection electrode CE1 and the first connection pattern CNP1 may be formed to be relatively small. Accordingly, the electrical characteristics of the display device DD may not be affected. Accordingly, the electrical characteristics of the display device DD may be improved or enhanced.

In an embodiment, the display device DD may further include a second reflective electrode RE2, a second connection pattern CNP2, a second connection electrode CE2, and an auxiliary electrode AE.

The second reflective electrode RE2 may be disposed in the peripheral area PA on the second structure ST2. In an embodiment, the first reflective electrode RE1 and the second reflective electrode RE2 may be spaced apart from each other. For example, the first reflective electrode RE1 and the second reflective electrode RE2 may be separate electrodes that are independent of each other.

The second reflective electrode RE2 and the first reflective electrode RE1 may be formed in the same process and may include the same material. For example, the second reflective electrode RE2 may have reflectivity to reflect incident light and may include a conductive material. Examples of the conductive material, which are used as the second reflective electrode RE2, may include metal, alloy, conductive metal oxide, conductive metal nitride, and the like. These may be used alone or in combination with each other. The second reflective electrode RE2 may have a single-layer structure or a multi-layer structure in which conductive layers are stacked.

The insulating layer IL may partially cover the second reflective electrode RE2. The insulating layer IL may define second contact holes CNT2 exposing a portion of the second reflective electrode RE2. For example, the number of second contact holes CNT2 shown in FIG. 2 is only an example and may vary depending on embodiments.

The second connection patterns CNP2 may be disposed on the second reflective electrode RE2. For example, the second connection patterns CNP2 may be respectively disposed in the second contact holes CNT2 of the insulating layer IL exposing the second reflective electrode RE2. For example, the second connection patterns CNP2 may respectively fill the second contact holes CNT2 of the insulating layer IL exposing the second reflective electrode RE2.

The second connection patterns CNP2 and the first connection pattern CNP1 may be formed in the same process and may include the same material process. For example, the second connection patterns CNP2 may include a conductive material. Examples of the conductive material, which are used as the second connection patterns CNP2, may include metal, alloy, conductive metal oxide, conductive metal nitride, and the like. These may be used alone or in combination with each other. For example, the second connection patterns CNP2 may include tungsten (W).

The second connection electrode CE2 may be disposed in the peripheral area PA on the insulating layer IL. The second connection electrode CE2 may be disposed on the second connection patterns CNP2. For example, the second connection electrode CE2 may overlap the second connection patterns CNP2 in a plan view and cover the second connection patterns CNP2. For example, the second connection electrode CE2 may cover the second connection patterns CNP2 exposed from the insulating layer IL.

In an embodiment, the first connection electrode CE1 and the second connection electrode CE2 may be spaced apart from each other. For example, the first connection electrode CE1 and the second connection electrode CE2 may be separate electrodes that are independent of each other.

The second connection electrode CE2 and the first connection electrode CE1 may be formed in the same process and may include the same material. For example, the second connection electrode CE2 may include a conductive material. Examples of the conductive material, which are used as the second connection electrode CE2, may include metal, alloy, conductive metal oxide, conductive metal nitride, and the like. These may be used alone or in combination with each other. The second connection electrode CE2 may have a single-layer structure or a multi-layer structure in which conductive layers are stacked.

For example, the second connection electrode CE2 may include titanium (Ti) and/or titanium nitride (TiN). In case that the second connection electrode CE2 includes titanium (Ti) and/or titanium nitride (TiN), durability of the second connection electrode CE2 may be further improved or enhanced.

For example, the second connection electrode CE2 may have the first electrical resistance. For example, the electrical resistance of the second connection electrode CE2 and the electrical resistance of the first connection electrode CE1 may be the same as each other. The first electrical resistance may be smaller than the electrical resistance of the auxiliary electrode AE, which will be described later. This will be described in more detail later.

The second connection electrode CE2 may be electrically connected to the second connection patterns CNP2. For example, the second connection electrode CE2 may contact the second connection patterns CNP2. For example, the second connection electrode CE2 may contact the second connection patterns CNP2 exposed from the insulating layer IL. As a result, the second connection electrode CE2 may be electrically connected to the second reflective electrode RE2 through the second connection patterns CNP2.

The auxiliary electrode AE may be disposed in the peripheral area PA on the insulating layer IL. The auxiliary electrode AE may be disposed on the second connection electrode CE2. For example, the auxiliary electrode AE may overlap the second connection electrode CE2 in a plan view.

In an embodiment, the first electrode E1 and the auxiliary electrode AE may be spaced apart from each other. For example, the first electrode E1 and the auxiliary electrode AE may be separate electrodes that are independent of each other.

The auxiliary electrode AE and the first electrode E1 may be formed in the same process and may include the same material. For example, the auxiliary electrode AE may include a conductive material. An example of the conductive material, which is used as the auxiliary electrode AE, may include transparent conductive oxide. For example, the auxiliary electrode AE may include indium tin oxide (ITO), indium gallium zinc oxide (IGZO), indium tin zinc oxide (ITZO), indium zinc oxide (IZO), indium gallium oxide (IGO), zinc oxide (ZnO), indium oxide (InO), tin oxide (SnO), gallium oxide (GaO), aluminum zinc oxide (AZO), and the like. These may be used alone or in combination with each other. The auxiliary electrode AE may have a single-layer structure or a multi-layer structure in which conductive layers are stacked.

For example, the auxiliary electrode AE may have the second electrical resistance greater than the first electrical resistance. For example, the electrical resistance of the auxiliary electrode AE may be the same as the electrical resistance of the first electrode E1. As a result, the auxiliary electrode AE may have a second electrical resistance greater than the first electrical resistance of the second connection electrode CE2. For example, the electrical resistance of the second connection electrode CE2 may be smaller than the electrical resistance of the auxiliary electrode AE. For example, the material included in the second connection electrode CE2 may have a smaller electrical resistance than the material included in the auxiliary electrode AE. For example, the material included in the first electrode E1 may be different from the material included in the first connection electrode CE1.

The auxiliary electrode AE may be electrically connected to the second connection electrode CE2. For example, the auxiliary electrode AE may contact the second connection electrode CE2. For example, the second connection electrode CE2 may contact the auxiliary electrode AE and the second connection patterns CNP2 between the auxiliary electrode AE and the second connection patterns CNP2. As a result, the auxiliary electrode AE may be electrically connected to the second connection patterns CNP2 through the second connection electrode CE2. For example, the auxiliary electrode AE may be electrically connected to the second reflective electrode RE2 through the second connection electrode CE2 and the second connection patterns CNP2.

Although the auxiliary electrode AE is electrically connected to the second connection patterns CNP2 by the second connection electrode CE2, the auxiliary electrode AE may not contact the second connection patterns CNP2. For example, the second connection electrode CE2 may cover the second connection patterns CNP2 between the auxiliary electrode AE and the second connection patterns CNP2, and accordingly, the auxiliary electrode AE may not contact the second connection patterns CNP2. For example, the second connection patterns CNP2 may not be exposed by the second connection electrode CE2, and accordingly, the auxiliary electrode AE may not contact the second connection patterns CNP2.

In case that the auxiliary electrode AE, which has a relatively large electrical resistance, contacts the second connection patterns CNP2, the contact resistance between the auxiliary electrode AE and the second connection patterns CNP2 may be large. Accordingly, the electrical characteristics of the display device DD may deteriorate or degrade.

According to an embodiment, the electrical resistance of the second connection electrode CE2 may be smaller than the electrical resistance of the auxiliary electrode AE, and the second connection electrode CE2 may be connected to the auxiliary electrode AE and the second connection patterns CNP2 may cover the second connection patterns CNP2. Accordingly, the auxiliary electrode AE may be electrically connected to the second connection patterns CNP2 through the second connection electrode CE2 while not contacting the second connection patterns CNP2. Accordingly, deterioration of the electrical characteristics of the display device DD due to contact between the auxiliary electrode AE, which has a relatively high electrical resistance, and the second connection patterns CNP2 may be prevented. For example, since the second connection electrode CE2 has a relatively small electrical resistance, although the second connection electrode CE2 contacts the second connection patterns CNP2, the contact resistance between the second connection electrode CE2 and the second connection patterns CNP2 may be formed to be relatively small. Accordingly, the electrical characteristics of the display device DD may not be affected. Accordingly, the electrical characteristics of the display device DD may be improved or enhanced.

For example, the second electrode E2 may contact the auxiliary electrode AE in the peripheral area PA. For example, the second electrode E2 may be electrically connected to the second reflective electrode RE2 through the auxiliary electrode AE, the second connection electrode CE2, and the second connection patterns CNP2. For example, the second reflective electrode RE2 may be connected to a power line that provides a power supply voltage (e.g., a low power supply voltage). For example, the second electrode E2 may receive the power supply voltage (e.g., low power supply voltage) through the auxiliary electrode AE, the second connection electrode CE2, and the second connection patterns CNP2. For example, the auxiliary electrode AE, the second connection electrode CE2, the second connection patterns CNP2, and the second reflective electrode RE2 may function as a path for transmitting the power voltage to the second electrode E2.

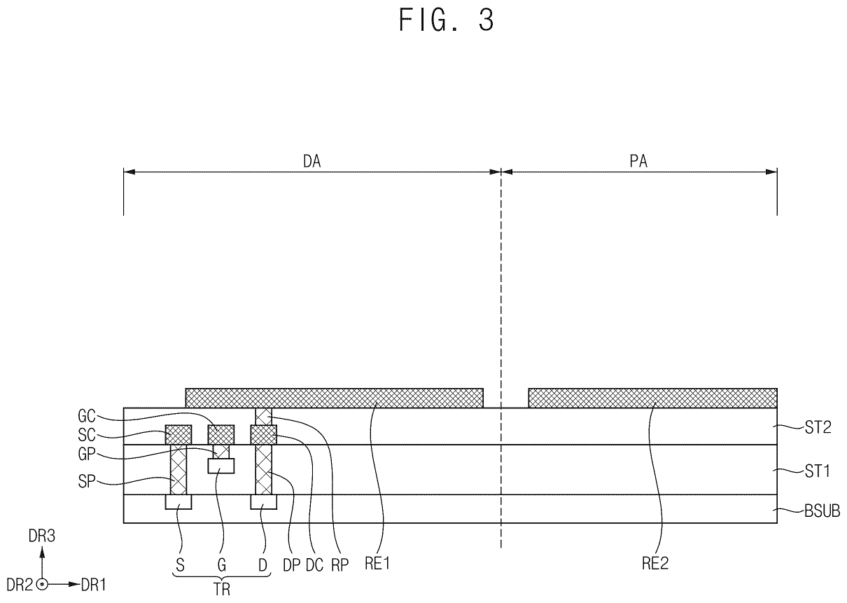

FIGS. 3, 4, 5, 6, 7, 8, 9, 10, and 11 are schematic cross-sectional views showing a method of manufacturing the display device of FIG. 2.

Hereinafter, the method of manufacturing the display device DD according to the embodiment described with reference to FIG. 2 will be described with reference to FIGS. 3, 4, 5, 6, 7, 8, 9, 10, and 11. For the same components described with reference to FIG. 2, overlapping descriptions will be omitted or simplified.

Referring to FIG. 3, the transistor TR, the first structure ST1, the first, second, and third terminal connection parts SP, DP, and GP, first, second, and third terminal electrodes SC, DC, and GC, the second structure ST2, and the electrode connection part RP may be formed. Thereafter, the first reflective electrode RE1 and the second reflective electrode RE2 may be formed on the second structure ST2. The first reflective electrode RE1 may be formed on the electrode connection part RP in the display area DA, and the second reflective electrode RE2 may be formed in the peripheral area PA.

In an embodiment, the first reflective electrode RE1 and the second reflective electrode RE2 may be formed together through the same process. For example, a first conductive film may be formed on the first structure ST1, and the first conductive film may be patterned to form the first reflective electrode RE1 and the second reflective electrode RE2. The first conductive layer may include a conductive material. Examples of the conductive material, which are used as the first conductive layer, may include metal, alloy, conductive metal oxide, conductive metal nitride, and the like. These may be used alone or in combination with each other. The first conductive film may have a single-layer structure or a multi-layer structure in which conductive layers are stacked.

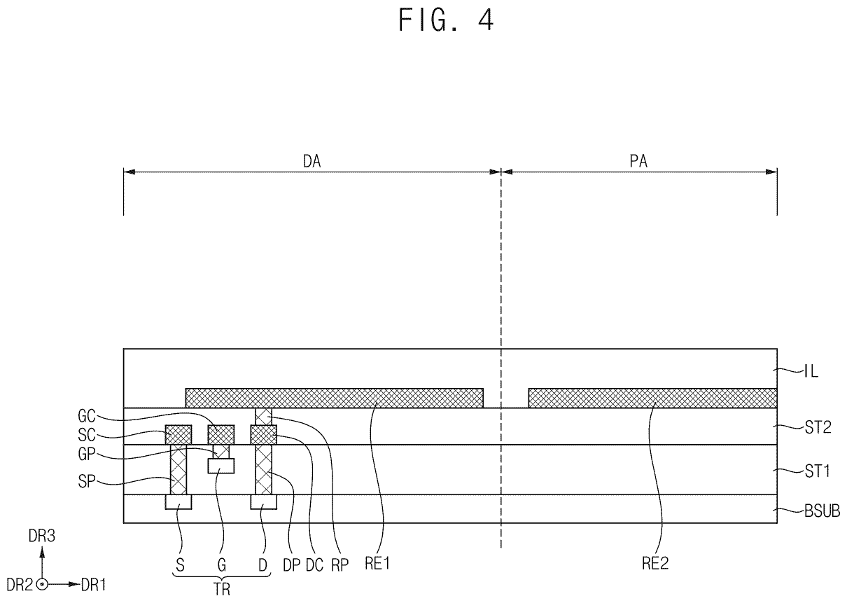

Referring to FIG. 4, the insulating layer IL may be formed on the second structure ST2. The insulating layer IL may be formed (e.g., entirely formed) in the display area DA and the peripheral area PA. The insulating layer IL may be formed to cover the first reflective electrode RE1 and the second reflective electrode RE2. In an embodiment, the insulating layer IL may be formed of an inorganic material.

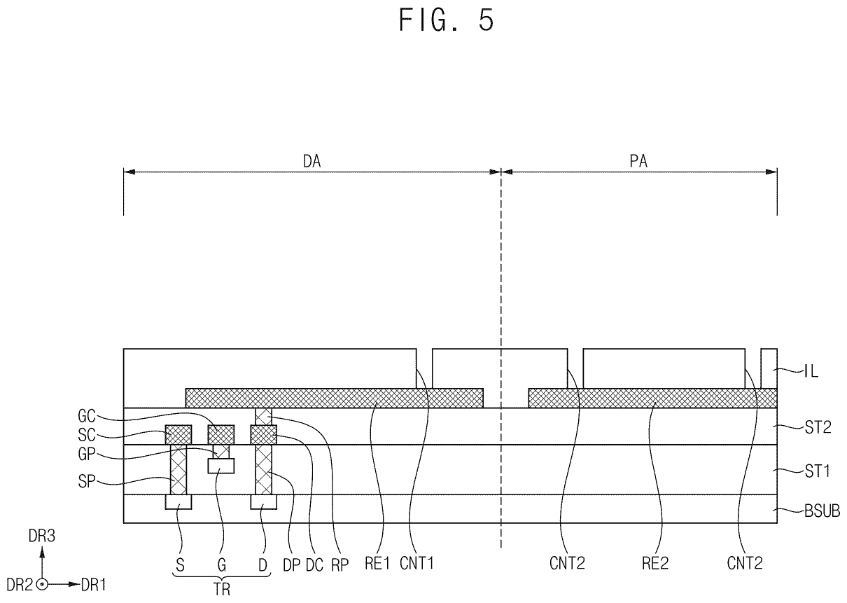

Referring to FIG. 5, a portion of the insulating layer IL may be removed to form the first contact hole CNT1 and the second contact holes CNT2. The first contact hole CNT1 may be formed in the display area DA, and the second contact holes CNT2 may be formed in the peripheral area PA. A portion of the first reflective electrode RE1 may be exposed through the first contact hole CNT1, and a portion of the second reflective electrode RE2 may be exposed through the second contact holes CNT2. In an embodiment, the first contact hole CNT1 and the second contact holes CNT2 may be formed by removing a portion of the insulating layer IL through an etching process. However, embodiments are not limited thereto.

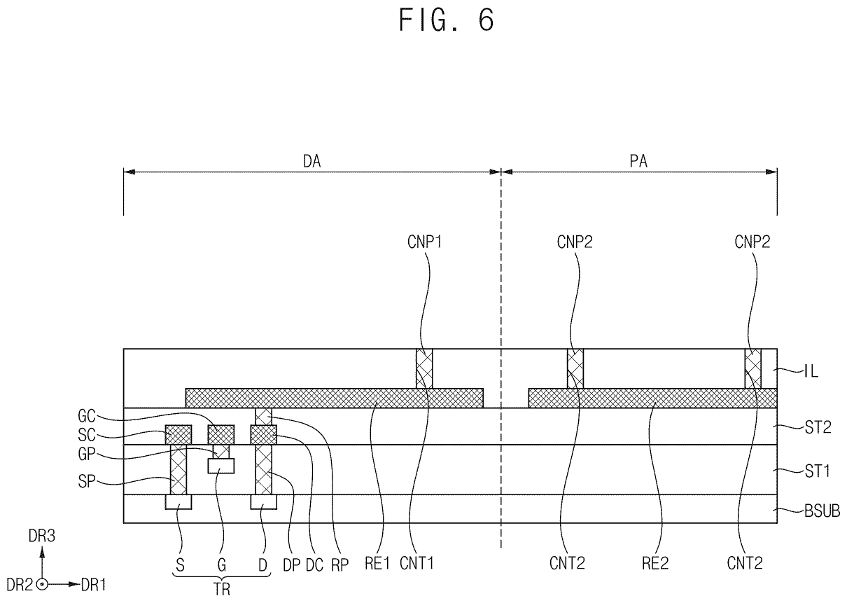

Referring to FIG. 6, the first connection patterns CNP1 and the second connection patterns CNP2 may be formed. The first connection pattern CNP1 may be formed in the first contact hole CNT1. For example, the first connection pattern CNP1 may be formed to fill the first contact hole CNT1. The second connection patterns CNP2 may be formed in each of the second contact holes CNT2. For example, the second connection patterns CNP2 may be formed to fill each of the second contact holes CNT2.

In an embodiment, the first connection pattern CNP1 and the second connection patterns CNP2 may be formed together in the same process. For example, the first connection pattern CNP1 and the second connection patterns CNP2 may be formed by forming a second conductive layer to fill the first contact hole CNT1 and the second contact hole CNT2 on the insulating layer IL and removing a portion of the second conductive film positioned on the insulating layer IL through a polishing process. However, embodiments are not limited thereto.

The second conductive layer may be formed of a conductive material. Examples of the conductive material, which are used as the second conductive layer, may include metal, alloy, conductive metal oxide, conductive metal nitride, and the like. These may be used alone or in combination with each other. For example, the second conductive layer may include tungsten (W).

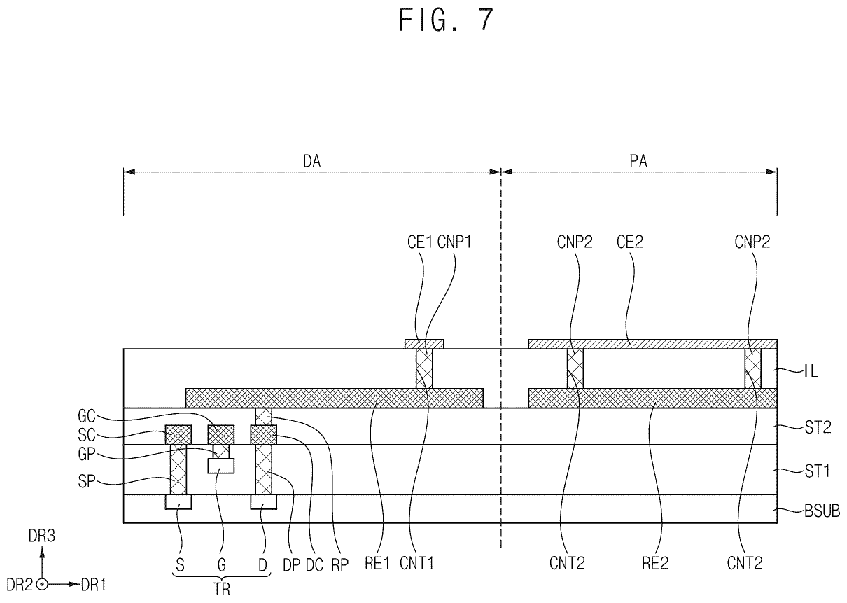

Referring to FIG. 7, the first connection electrode CE1 and the second connection electrode CE2 may be formed on the insulating layer IL. The first connection electrode CE1 may be formed in the display area DA, and the second connection electrode CE2 may be formed in the peripheral area PA. For example, the first connection electrode CE1 may be formed to cover the first connection pattern CNP1, and the second connection electrode CE2 may be formed to cover the second connection patterns CNP2.

In an embodiment, the first connection electrode CE1 and the second connection electrode CE2 may be formed together through the same process. For example, a third conductive film may be formed on the insulating layer IL, and the third conductive film may be patterned to form the first and second connection electrodes CE1 and CE2. The third conductive layer may be formed of a conductive material. Examples of the conductive material, which is used as the third conductive layer, may include metal, alloy, conductive metal oxide, conductive metal nitride, and the like. These may be used alone or in combination with each other. For example, the third conductive layer may be formed of titanium (Ti) and/or titanium nitride (TiN). The third conductive film may have a single-layer structure or a multi-layer structure in which conductive layers are stacked.

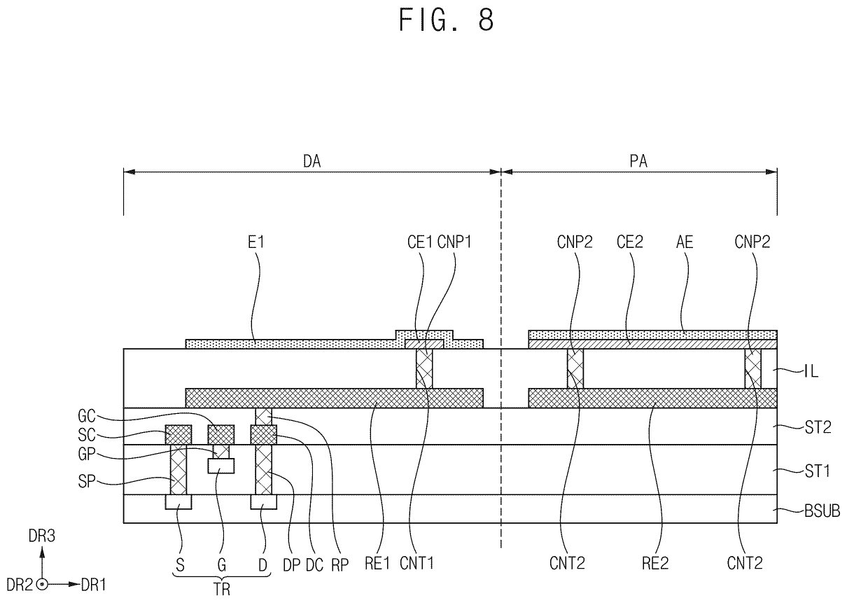

Referring to FIG. 8, the first electrode E1 and the auxiliary electrode AE may be formed on the insulating layer IL. The first electrode E1 may be formed in the display area DA, and the auxiliary electrode AE may be formed in the peripheral area PA. For example, the first electrode E1 may be formed on the first connection electrode CE1, and the auxiliary electrode AE may be formed on the second connection electrode CE2.

In an embodiment, the first electrode E1 and the auxiliary electrode AE may be formed together through the same process. For example, a fourth conductive film may be formed on the insulating layer IL, the first connection electrode CE1, and the second connection electrode CE2, and the fourth conductive film may be patterned to form the first electrode E1 and the auxiliary electrode AE. The fourth conductive layer may be formed of a conductive material. An example of the conductive material, which is used as the fourth conductive film, may include transparent conductive oxide. For example, the fourth conductive layer may include indium tin oxide (ITO), indium gallium zinc oxide (IGZO), indium tin zinc oxide (ITZO), indium zinc oxide (IZO), indium gallium oxide (IGO), zinc oxide (ZnO), indium oxide (InO), tin oxide (SnO), gallium oxide (GaO), aluminum zinc oxide (AZO), and the like. These may be used alone or in combination with each other. The fourth conductive film may have a single-layer structure or a multi-layer structure in which conductive layers are stacked.

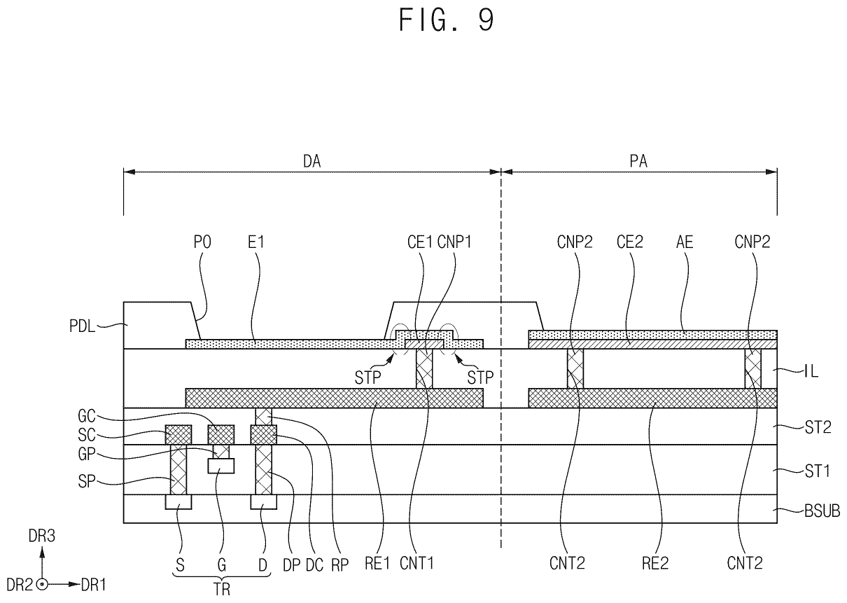

Referring to FIG. 9, the pixel defining layer PDL may be formed on the insulating layer IL, the first electrode E1, and the auxiliary electrode AE. The pixel defining layer PDL may be formed by forming a preliminary layer including an organic material and/or an inorganic material, and patterning the preliminary layer on the insulating layer IL, the first electrode E1, and the auxiliary electrode AE. The pixel defining layer PDL may be formed to overlap the first connection electrode CE1 in a plan view. For example, the pixel defining layer PDL may be formed to cover the step section STP of the first electrode E1.

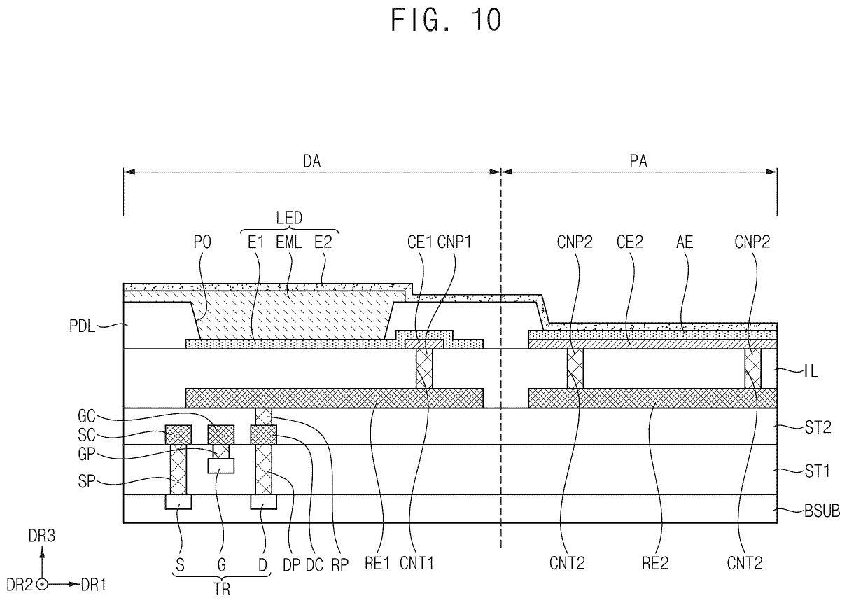

Referring to FIG. 10, the intermediate layer ML and the second electrode E2 may be formed on the first electrode E1, the auxiliary electrode AE, and the pixel defining layer PDL.

The intermediate layer ML may be formed in the display area DA and may be disposed in the pixel opening PO of the pixel defining layer PDL. In an embodiment, the intermediate layer ML may be formed in a structure in which at least one functional layer including an organic material and at least one light emitting layer including a light emitting material are stacked.

The second electrode E2 may be formed in the display area DA and the peripheral area PA, and may be formed to contact the auxiliary electrode AE in the peripheral area PA. The second electrode E2 may be formed of a conductive material. Examples of the conductive material, which are used as the second electrode E2, may include metal, alloy, conductive metal oxide, conductive metal nitride, transparent conductive oxide, and the like. These may be used alone or in combination with each other. In an embodiment, the second electrode E2 may be formed to have semi-transparency or transparency.

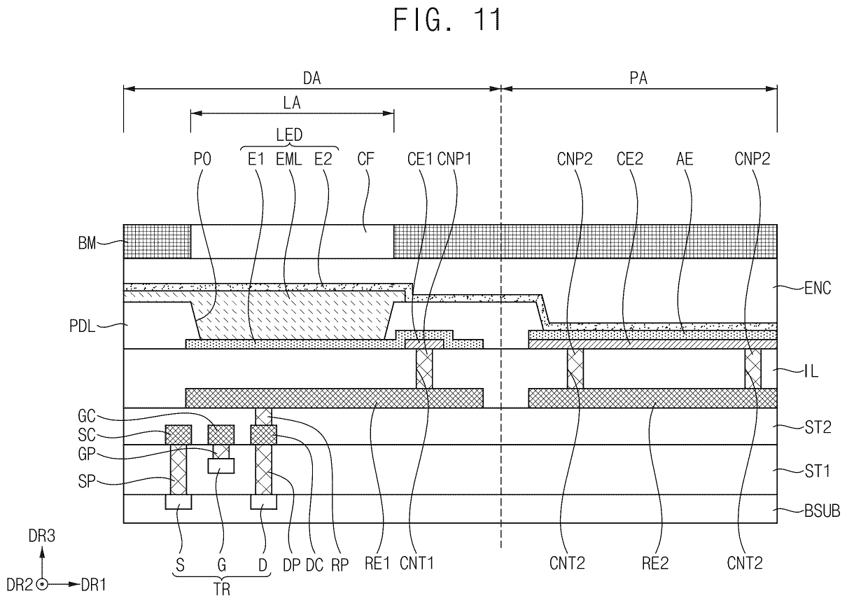

Referring to FIG. 11, the encapsulation layer ENC may be formed on the second electrode E2, and the light blocking member BM and the color filter CF may be formed on the encapsulation layer ENC. The light emitting area LA may be defined by the light blocking member BM. As described above, in an embodiment, the light blocking member BM may be formed of an organic material and/or an inorganic material including black pigment, black dye, and the like. However, embodiments are not limited thereto, and the light blocking member BM and the color filter CF may be formed by the same process. For example, the light blocking member BM may be formed in a structure in which color filters of different colors are stacked in the third direction DR3.

Thereafter, as shown in FIG. 2, the cover member CV may be formed on the light blocking member BM and the color filter CF.

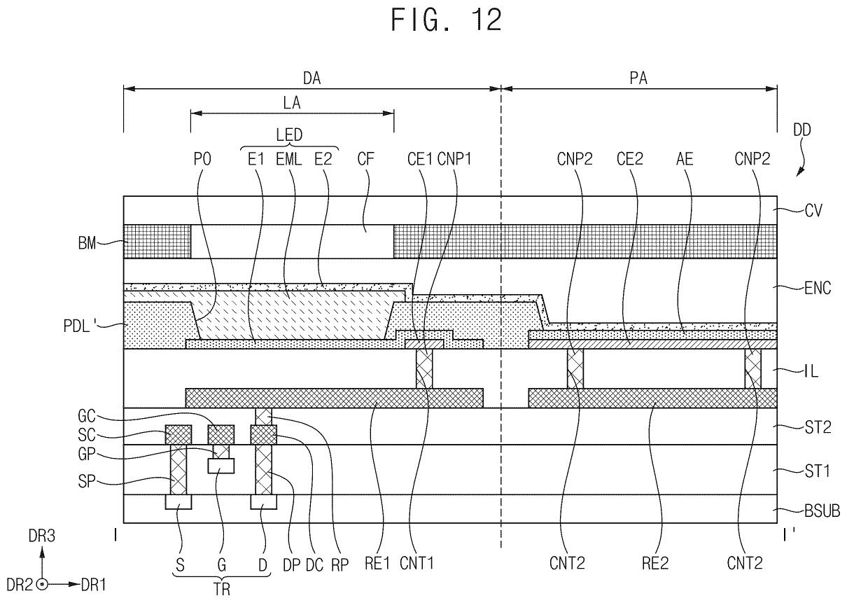

FIG. 12 is a schematic cross-sectional view showing another example taken along line I-I′ of FIG. 1.

An embodiment of the display device DD described with reference to FIG. 12 may be substantially the same as the embodiment of the display device DD described with reference to FIG. 2, except that the pixel defining layer PDL′ includes a light blocking material. For example, the pixel defining layer PDL′ of FIG. 12 may be substantially the same as the pixel defining layer PDL of FIG. 2 except that the pixel defining layer PDL′ includes the light blocking material. Therefore, redundant descriptions are omitted.

In an embodiment, the pixel defining layer PDL′ may include a light blocking material. For example, the pixel defining layer PDL′ may include an organic material and/or an inorganic material including black pigment, black dye, and the like. According to an embodiment in which the pixel defining layer PDL′ includes the light blocking material, external light reflection by the first connection electrode CE1 disposed under the pixel defining layer PDL′ may be further reduced or prevented. For example, the phenomenon of the first connection electrode CE1 being visible from the outside may be further reduced or prevented.

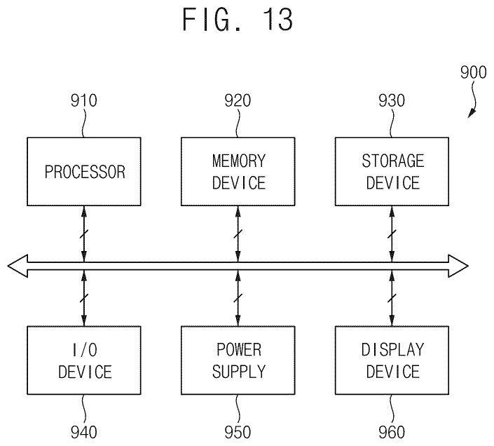

FIG. 13 is a schematic block diagram illustrating an electronic device according to an embodiment.

Referring to FIG. 13, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1, 2, and 12. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The disclosure can be applied to various display devices. For example, the disclosure is applicable to various display devices such as display devices for vehicles, ships and aircraft, portable communication devices, display devices for exhibition or information transmission, medical display devices, and the like.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a first reflective electrode including a conductive material;
an insulating layer partially covering the first reflective electrode;
a first connection pattern disposed in a first contact hole of the insulating layer exposing at least a portion of the first reflective electrode and electrically connected to the first reflective electrode;
a first connection electrode disposed on the insulating layer, electrically connected to the first connection pattern, and having a first electrical resistance; and
a light emitting element including a first electrode disposed on the insulating layer and the first connection electrode, electrically connected to the first connection electrode, and having a second electrical resistance greater than the first electrical resistance.

2. The display device of claim 1, wherein the first connection electrode overlaps the first contact hole in a plan view and covers the first connection pattern.

3. The display device of claim 1, wherein the first electrode is electrically connected to the first reflective electrode through the first connection electrode and the first connection pattern.

4. The display device of claim 1, wherein the first connection electrode contacts the first electrode and the first connection pattern between the first electrode and the first connection pattern.

5. The display device of claim 1, wherein the first electrode does not contact the first connection pattern.

6. The display device of claim 1, further comprising:
a pixel defining layer disposed on the insulating layer, partially covering the first electrode, and defining a pixel opening exposing a portion of the first electrode,
wherein the first connection electrode overlaps the pixel defining layer in a plan view.

7. The display device of claim 6, wherein the first connection electrode is spaced apart from the pixel opening in a plan view.

8. The display device of claim 6, wherein
the first electrode has a step section defined along a sidewall of the first connection electrode, and
the pixel defining layer covers the step section of the first electrode.

9. The display device of claim 1, wherein the first connection electrode and the first electrode include different materials.

10. The display device of claim 1, wherein the first electrode includes a transparent conductive oxide.

11. The display device of claim 1, wherein the first connection electrode includes at least one of metal, alloy, and conductive metal nitride.

12. The display device of claim 1, further comprising:
a transistor electrically connected to the first reflective electrode and that drives the light emitting element.

13. The display device of claim 12, wherein the first electrode is electrically connected to the transistor through the first connection electrode, the first connection pattern, and the first reflective electrode.

14. The display device of claim 1, wherein the insulating layer includes an inorganic material and has light transparency.

15. The display device of claim 1, wherein the light emitting element includes:
an intermediate layer disposed on the first electrode and including a light emitting material; and
a second electrode disposed on the intermediate layer.

16. The display device of claim 15, further comprising:
an auxiliary electrode disposed on the insulating layer, the auxiliary electrode and the first electrode including a same material,
wherein the second electrode contacts the auxiliary electrode in an area.

17. The display device of claim 16, further comprising:
a second reflective electrode disposed under the auxiliary electrode in the area and partially covered by the insulating layer, the second reflective electrode and the first reflective electrode including a same material;
a second connection pattern disposed in a second contact hole of the insulating layer exposing at least portion of the second reflective electrode and electrically connected to the second reflective electrode; and
a second connection electrode disposed on the insulating layer and electrically connected to the second connection pattern, the second connection electrode and the first connection electrode including a same material,
wherein the second connection electrode has the first electrical resistance and the auxiliary electrode has the second electrical resistance.

18. The display device of claim 17, wherein the second connection electrode overlaps the second contact hole in a plan view and covers the second connection pattern.

19. The display device of claim 17, wherein the auxiliary electrode is electrically connected to the second reflective electrode through the second connection electrode and the second connection pattern.

20. The display device of claim 17, wherein
the second connection electrode contacts the auxiliary electrode and the second connection pattern between the auxiliary electrode and the second connection pattern, and
the auxiliary electrode does not contact the second connection pattern.

21. An electronic device comprising:
a display device; and
a processor which controls the display device,
wherein the display device includes:
a first reflective electrode including a conductive material;
an insulating layer partially covering the first reflective electrode;
a first connection pattern disposed in a first contact hole of the insulating layer exposing at least a portion of the first reflective electrode and electrically connected to the first reflective electrode;
a first connection electrode disposed on the insulating layer, electrically connected to the first connection pattern, and having a first electrical resistance; and
a light emitting element including a first electrode disposed on the insulating layer and the first connection electrode, electrically connected to the first connection electrode, and having a second electrical resistance greater than the first electrical resistance.
